(19) United States
(12) Patent Application Publication
(10) Pub. No.: US 2024/0145392 A1
(43) Pub. Date: May 2, 2024

(54) Substrate with Differing Dielectric Constants

(71) Applicant: Avago Technologies International Sales Pte. Limited, Singapore (SG)

(72) Inventors: Dharmendra Saraswat, Foothill Ranch, CA (US); Mayank Mayukh, Fort Collins, CO (US); Reza Sharifi, Irvine, CA (US); Sam Zhao, Irvine, CA (US); Kwok Cheung Tsang, Irvine, CA (US); Vincent Huang, Hsinchu City (TW); Jevon Yu, Hsinchu City (TW); Sam Karikalan, Irvine, CA (US); Arun Ramakrishnan, Lake Forest, CA (US); Liming Tsau, Irvine, CA (US)

(21) Appl. No.: 17/977,401

(22) Filed: Oct. 31, 2022

(51) Int. Cl. H01L 23/532; H01L 21/02; H01L 21/768; H01L 23/528

(52) U.S. Cl. CPC H01L 23/5329; H01L 21/02123; H01L 21/76837; H01L 23/528

(57) ABSTRACT

A substrate with differing dielectric constant materials is provided. The substrate includes a first ground plane, a second ground plane, a first conductive trace, a first material having a first dielectric constant, and a second material having a second dielectric constant. The first material is disposed between the first ground plane and the first conductive trace, and the second material is disposed between the second ground plane and at least part of the first conductive trace. The first dielectric constant is different from the second dielectric constant.

### COPYRIGHT STATEMENT

A portion of the disclosure of this patent document contains material that is subject to copyright protection. The copyright owner has no objection to the facsimile reproduction by anyone of the patent document or the patent disclosure as it appears in the Patent and Trademark Office patent file or records, but otherwise reserves all copyright rights whatsoever.

### FIELD

The present disclosure relates, in general, to methods, systems, and apparatuses for a substrate with differing dielectric constants

### BACKGROUND

Differential signaling is a technique in which two paired conductors are used to carry complementary signals. Conventional high speed differential pair/single end trace designs are homogeneous, using a fixed trace width from the escape area (e.g., the area for escape routing around bumps) to the global area (e.g., the area for global routing). Impedance dips in the package ball area are caused by large fringe capacitance, which results in worsened insertion loss (IL) and return loss (RL). Furthermore, the thickness of the dielectric material under the high speed traces is typically a uniform thickness. IL is typically controlled by modification of the total cross-sectional area of the high speed trace, with wider traces yielding better (reduced) IL.

Differential pairs also typically exhibit mismatches in electrical length. Traditional techniques for electrical length matching in differential pairs, such as serpentine traces, lead to higher IL, RL, and inaccurate electrical length matching.

Thus, methods, systems, and apparatuses for a substrate with differing dielectric constants (D_{K}) are provided.

### BRIEF DESCRIPTION OF THE DRAWINGS

A further understanding of the nature and advantages of particular embodiments may be realized by reference to the remaining portions of the specification and the drawings, in which like reference numerals are used to refer to similar components. In some instances, a sub-label is associated with a reference numeral to denote one of multiple similar components. When reference is made to a reference numeral without specification to an existing sub-label, it is intended to refer to all such multiple similar components.

FIG. 1A is a schematic top view of a differential pair of conductive traces of a substrate with a dielectric insert, in accordance with various embodiments;

FIG. 1B is a schematic diagram of a cross-section of the substrate with a dielectric insert, in accordance with various embodiments;

FIG. 2 is a schematic diagram of a longitudinal section of a substrate with variable dielectric thickness, in accordance with various embodiments;

FIG. 3A is a schematic diagram of a top view of a substrate with variable conductive trace width, in accordance with various embodiments;

FIG. 3B is a schematic diagram of a top view of an alternative substrate with variable conductive trace width, in accordance with various embodiments;

FIG. 4 is a block diagram of a semiconductor device having a substrate with differing dielectric constants, in accordance with various embodiments;

FIG. 5 is a flow diagram of a method of manufacturing a substrate with differing dielectric constant, in accordance with various embodiments.

### DETAILED DESCRIPTION OF EMBODIMENTS

Various embodiments set forth a substrate and semiconductor device with differing dielectric constants, and methods of manufacturing a substrate with differing dielectric constants.

In some embodiments, an apparatus for a substrate with differing dielectric constants is provided. The apparatus includes a first ground plane, a second ground plane, a first conductive trace, a first material, and a second material. The first material has a first dielectric constant, wherein the first material is disposed between the first ground plane and the first conductive trace. The second material has a second dielectric constant, wherein the second material is disposed between the second ground plane and at least part of the first conductive trace. The first dielectric constant is different from the second dielectric constant.

In further embodiments, a semiconductor device including a substrate with differing dielectric constants is provided. The semiconductor device includes a substrate, and a die coupled to the substrate. The substrate includes a first ground plane, a second ground plane, a first conductive trace, and one or more build-up layers formed of a first material having a first dielectric constant, wherein the one or more build-up layers are disposed between the first ground plane and the first conductive trace. The substrate further includes a dielectric insert, the dielectric insert formed of a second material having a second dielectric constant, wherein the dielectric insert is disposed between the second ground plane and at least part of the first conductive trace. The first dielectric constant is different from the second dielectric constant.

In further embodiments, a method of manufacturing a substrate with differing dielectric constants is provided. The method includes forming one or more build-up layers of a substrate from a first material having a first dielectric constant, positioning one or more placeholders on at least one of the one or more build-up layers, each placeholder of the one or more placeholders defining walls of a respective cavity of one or more cavities, laminating the one or more build-up layers, and forming one or more outer layers of the substrate. The method further includes forming a dielectric insert within the one or more cavities formed by the placeholders.

In the following description, for the purposes of explanation, numerous details are set forth to provide a thorough understanding of the described embodiments. It will be apparent to one skilled in the art, however, that other embodiments may be practiced without some of these details. Several embodiments are described herein, and while various features are ascribed to different embodiments, it should be appreciated that the features described with respect to one embodiment may be incorporated with other embodiments as well. By the same token, however, no single feature or features of any described embodiment should be considered essential to every embodiment of the invention, as other embodiments of the invention may omit such features.

When an element is referred to herein as being “connected” or “coupled” to another element, it is to be understood that the elements can be directly connected to the other element, or have intervening elements present between the elements. In contrast, when an element is referred to as being “directly connected” or “directly coupled” to another element, it should be understood that no intervening elements are present in the “direct” connection between the elements. However, the existence of a direct connection does not exclude other connections, in which intervening elements may be present.

When an element is referred to herein as being “disposed” in some manner relative to another element (e.g., disposed on, disposed between, disposed under, disposed adjacent to, or disposed in some other relative manner), it is to be understood that the elements can be directly disposed relative to the other element (e.g., disposed directly on another element), or have intervening elements present between the elements. In contrast, when an element is referred to as being “disposed directly” relative to another element, it should be understood that no intervening elements are present in the “direct” example. However, the existence of a direct disposition does not exclude other examples in which intervening elements may be present.

Similarly, when an element is referred to herein as being “bonded” to another element, it is to be understood that the elements can be directly bonded to the other element (without any intervening elements) or have intervening elements present between the bonded elements. In contrast, when an element is referred to as being “directly bonded” to another element, it should be understood that no intervening elements are present in the “direct” bond between the elements. However, the existence of direct bonding does not exclude other forms of bonding, in which intervening elements may be present.

Likewise, when an element is referred to herein as being a “layer,” it is to be understood that the layer can be a single layer or include multiple layers. For example, a conductive layer may comprise multiple different conductive materials or multiple layers of different conductive materials, and a dielectric layer may comprise multiple dielectric materials or multiple layers of dielectric materials. When a layer is described as being coupled or connected to another layer, it is to be understood that the coupled or connected layers may include intervening elements present between the coupled or connected layers. In contrast, when a layer is referred to as being “directly” connected or coupled to another layer, it should be understood that no intervening elements are present between the layers. However, the existence of directly coupled or connected layers does not exclude other connections in which intervening elements may be present.

Moreover, the terms left, right, front, back, top, bottom, forward, reverse, clockwise and counterclockwise are used for purposes of explanation only and are not limited to any fixed direction or orientation. Rather, they are used merely to indicate relative locations and/or directions between various parts of an object and/or components.

Furthermore, the methods and processes described herein may be described in a particular order for ease of description. However, it should be understood that, unless the context dictates otherwise, intervening processes may take place before and/or after any portion of the described process, and further various procedures may be reordered, added, and/or omitted in accordance with various embodiments.

Unless otherwise indicated, all numbers used herein to express quantities, dimensions, and so forth should be understood as being modified in all instances by the term “about.” In this application, the use of the singular includes the plural unless specifically stated otherwise, and use of the terms “and” and “or” means “and/or” unless otherwise indicated. Moreover, the use of the terms “including” and “having,” as well as other forms, such as “includes,” “included,” “has,” “have,” and “had,” should be considered non-exclusive. Also, terms such as “element” or “component” encompass both elements and components comprising one unit and elements and components that comprise more than one unit, unless specifically stated otherwise.

As used herein, the phrase “at least one of” preceding a series of items, with the term “and” or “or” to separate any of the items, modifies the list as a whole, rather than each member of the list (i.e., each item). The phrase “at least one of” does not require selection of at least one of each item listed; rather, the phrase allows a meaning that includes at least one of any one of the items, and/or at least one of any combination of the items. By way of example, the phrases “at least one of A, B, and C” or “at least one of A, B, or C” each refer to only A, only B, or only C; and/or any combination of A, B, and C. In instances where it is intended that a selection be of “at least one of each of A, B, and C,” or alternatively, “at least one of A, at least one of B, and at least one of C,” it is expressly described as such.

Differential pairs having mismatched electrical length often result in increased IL and RL. Impedance dips also occur in the package ball area, which is caused by large fringe capacitance, which also results in worsened IL and RL in the package. Higher density areas, like bump areas (near dies) typically limit the maximum width of a trace, which in turn limits maximum cross-sectional area of the trace.

In some embodiments, a proposed substrate with differing dielectric constants provides a way to address these problems. By selectively placing a dielectric insert of a different dielectric constant (Dₖ) (e.g., lower than surrounding dielectric build-up material), the electrical length of a “longer” trace in a differential pair may be adjusted (e.g., decreased). Moreover, impedance dips may be controlled by placement of dielectric inserts around the package ball areas. The width of a conductive trace may also be variable, based on proximity to the bump area of a die and/or thickness of a dielectric material, which may further be adjusted by selective placement of the dielectric inserts.

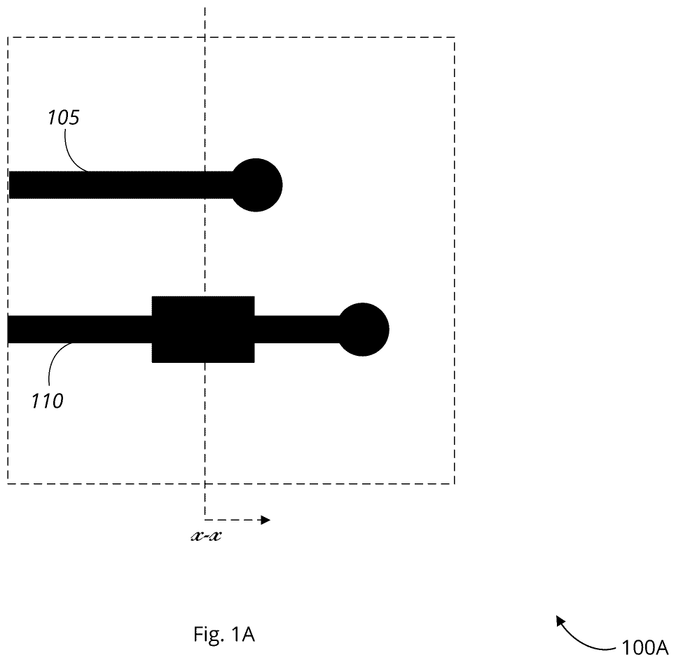

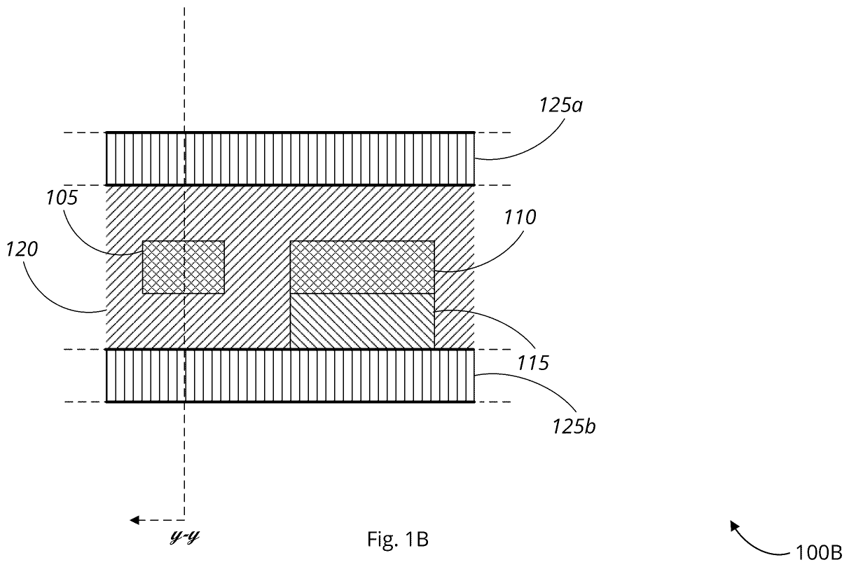

FIG. 1A is a schematic top view of a pair of conductive traces of a substrate 100A with a dielectric insert, in accordance with various embodiments. The substrate 100A includes a first conductive trace 105 and second conductive trace 110. It should be noted that the various components of substrate 100A are schematically illustrated in FIG. 1A, and that modifications to the various components and other arrangements of substrate 100A may be possible and in accordance with the various embodiments.

In various embodiments, the substrate 100A may be a semiconductor substrate. In some examples, the substrate 100A may include a chip carrier die, printed circuit board (PCB), or other suitable substrate for die placement. In some examples, the substrate 100A may include two or more internal layers (e.g., routing layers), through which component interconnects may be present. In various examples, interconnects may include conductive traces, such as copper (Cu) traces and/or traces formed from other metals.

Accordingly, in various embodiments, the substrate 100A may include a first trace 105 and second trace 110. In some examples, the first trace 105 and second trace 110 may be a differential pair. A differential pair may be a pair of signal lines (in this example, conductive traces) that are configured to carry complementary signals. Complementary signals are signals of the same magnitude, but of opposite polarity. In further examples, the first conductive trace 105 and second conductive trace 110 are copper traces.

In some examples, the first conductive trace 105 may have a first electrical length, while the second conductive trace 110 has a second electrical length. As used herein, electrical length (also commonly referred to as “phase length”) refers to the phase shift introduced to a periodic signal by a transmission line (e.g., the conductive trace). In some further examples, the conductive trace, such as the second conductive trace 110, may include a conductive pad and/or an area in which the conductive trace has been widened.

In various examples, the substrate 100A may be formed from one or more layers of dielectric material, which have been laminated together. In some examples, the substrate 100A includes a first material having a first dielectric constant, and a second material having a second dielectric constant different from the first. In some examples, the first dielectric constant may be in the range of 2.5-5. The second dielectric constant may be in the range of 1.0-2.0. In various embodiments, the first material and/or second material may be selective placed in positions relative to the first conductive trace 105 and/or second conductive trace 110 and respective ground planes (not shown) of the substrate 100A.

In some examples, the first conductive trace 105 may have a shorter (e.g., smaller) electrical length relative to the second conductive trace 110. To match the electrical length of the first and second conductive traces 105, 110, a dielectric insert may be formed under the second conductive trace 110, between the second conductive trace 110 and a respective ground plane. As used herein, a dielectric insert may refer to a piece of dielectric material that is selectively formed in the substrate 100A. Formation of the dielectric insert may include deposition of dielectric material, injection, insertion, or other process by which the dielectric material may be placed into position. A ground plane may refer to a metallization layer formed on a top surface and/or bottom surface of the substrate to serve as electrical ground for circuits (or electrical components) formed in and/or coupled to the substrate 100A.

Placement of the dielectric insert is illustrated in greater detail with respect to FIG. 1B, which depicts a cross section taken along axis x-x, and viewed in the direction of the arrow.

FIG. 1B is a schematic diagram of a cross-section of the substrate 100B with a dielectric insert, in accordance with various embodiments. The substrate 100B includes the first conductive trace 105, second conductive trace 110, dielectric insert 115, dielectric build-up 120, first ground plane 125a, and second ground plane 125b. It should be noted that the various components of substrate 100B are schematically illustrated in FIG. 1B, and that modifications to the various components and other arrangements of substrate 100b may be possible and in accordance with the various embodiments.

As previously described, a dielectric insert 115 may be disposed between the second conductive trace 110 and second ground plane 125b. In various embodiments, the dielectric insert 115 may be selectively placed under the conductive trace having a longer electrical length, in this example, the second conductive trace 110. The length of the dielectric insert 115 may, in some examples, be adjusted or tuned to mitigate an electrical skew within the differential pair, effectively matching and/or bringing the electrical lengths of the respective conductive traces 105, 110 closer together.

As previously described, in some examples, the dielectric insert 115 is a piece of dielectric material that has a lower Dₖ than the dielectric material of the dielectric build-up 120. In some examples, the dielectric insert 115 may be formed under the second conductive trace 110. In various embodiments, the dielectric material of the dielectric insert 115 includes, without limitation, an aerogel, such as a silicon-based aerogel. In some examples, the aerogel may be a silica (SiO₂) aerogel. In other examples, instead a dielectric material, the dielectric insert 115 may instead be a hollow cavity filled with air or other fluid (gas or liquid), or a vacuum.

As used herein, dielectric build-up 120 refers to the one or more build-up layers of the substrate 100A, 100B. Thus, the dielectric build-up 120 may include one or more layers of dielectric material forming the substrate 100A, 100B itself, including the core of the substrate 100A, 100B. Dielectric build-up 120 may include, without limitation, build-up film or other laminate material. The dielectric build-up 120 includes, for example, pre-preg polymer and/or epoxy dielectric material, or a silicon-based dielectric material (e.g., Si₃N₄, SiO₂, etc.). The dielectric material of the dielectric build-up 120 may have a Dₖ different from the Dₖ of the dielectric insert 115.

In yet further examples, dielectric inserts 115 may be placed around conductive traces in areas near package ball areas (e.g., a ball grid array (BGA) and/or solder bump (including microbumps)) of a die package. Specifically, the areas near the package ball areas (also referred to as an “escape area” of the substrate 100A, 100B) are more densely populated with conductive traces than areas farther away from the die package (e.g., the “global area”). The lower Dₖ of the dielectric insert may be accordingly mitigate capacitance in the escape areas of the substrate 100A, 100B and in turn mitigate impedance dips in these areas.

In various examples, the first and second ground planes 125a, 125b may be a metallization layer formed on a top surface and bottom surface of the substrate 100A, 100B. In some examples, the first and second ground planes 125a, 125b may be formed via metal plating and/or a deposition process. For example, in some embodiments, the first and second ground planes 125a, 125b is formed via electroless (e-less) Cu plating.

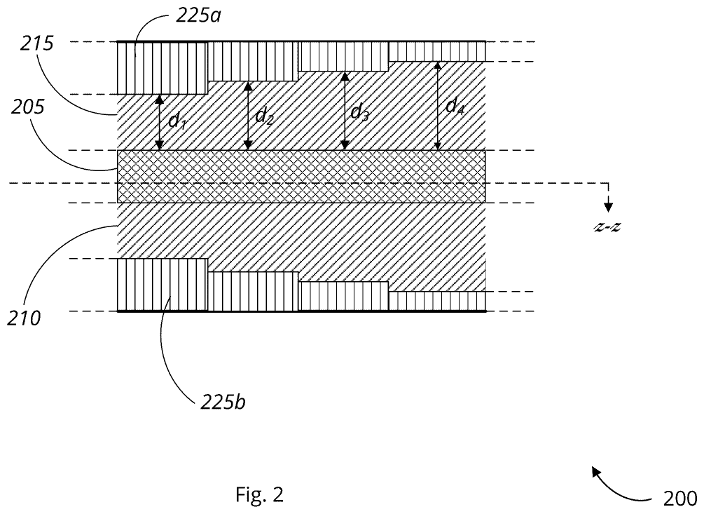

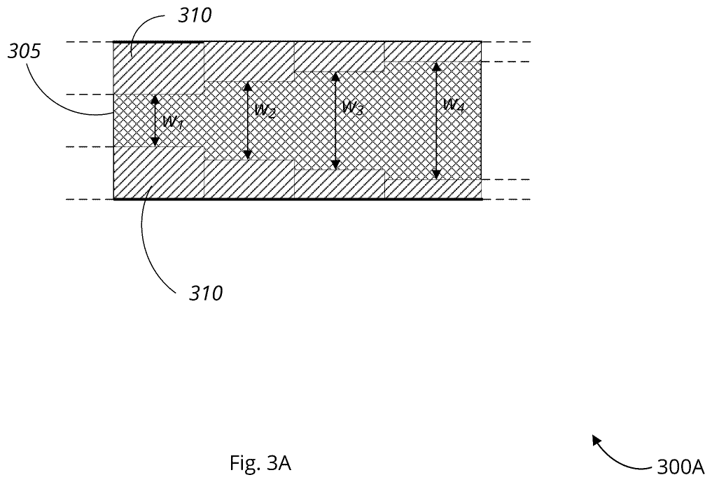

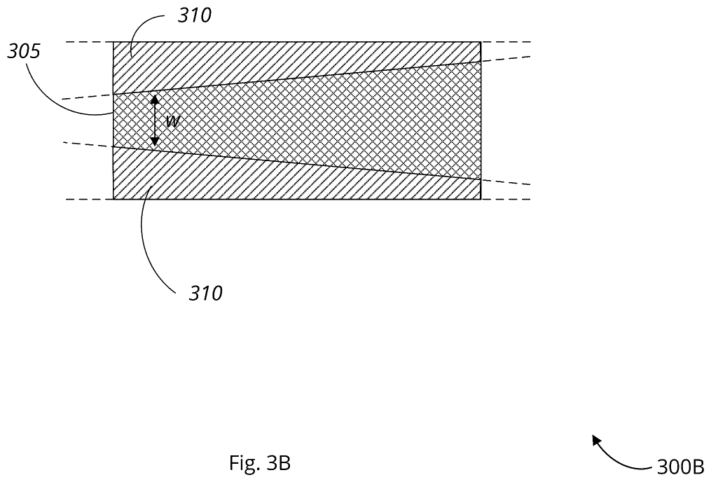

In some further examples, a thickness of the dielectric build-up 120 and/or the ground planes 125a, 125b may increase as the distance away from the die package increases. This is illustrated in greater below with respect to FIG. 2, which depicts a cross-section taken along axis y-y, and viewed in the direction of the arrow. A width of one or more of the conductive traces 105, 110 may also increase with the thickness of the dielectric material (e.g., dielectric build-up 120). This illustrated in greater detail with respect to FIGS. 3A, and 3B.

FIG. 2 is a schematic diagram of a longitudinal section of a substrate 200 with variable dielectric thickness, in accordance with various embodiments. The substrate 200 includes conductive trace 205, dielectric build-up 210, 215, and ground planes 225a, 225b. It should be noted that the various components of the substrate 200 are schematically illustrated in FIG. 2, and that modifications to the various components and other arrangements of the substrate 200 may be possible and in accordance with the various embodiments.

As in FIG. 1, FIG. 2 depicts a substrate having dielectric build-up 210 below the conductive trace 205 and dielectric build-up 215 above the conductive trace 205. As previously described, a first ground plane 225a may be formed at a top surface of the substrate 200, and second ground plane 225b formed at a bottom surface of the substrate 200.

In various embodiments, the thickness of the dielectric build-up 210, 215 (including dielectric core of the substrate 200) may be variable along the longitudinal axis z-z of the conductive trace 205. In some examples, a corresponding thickness of the ground planes 225a, 225b may also be variable along the axis z-z. In some examples, the thickness of the dielectric build-up 210, 215 increases with distance away from a die package (e.g., distance from an escape area). Correspondingly, in some examples, a thickness of the ground planes 225a, 225b may decrease with distance away from the die package.

In some examples, at a first range of distances away from the die package, the dielectric build-up 210, 215 may have a first thickness, d₁. At a second range of distances from the die package, the dielectric build-up 210, 215 may have a second thickness, d₂. The thickness of the dielectric build-up 210, 215 may increase in this step-wise manner based on ranges of distances. In other embodiments, the thickness of the dielectric build-up 210, 215 may increase continuously as a function of distance from the die package/escape area as opposed to the discrete steps depicted. In yet further embodiments, a thickness of the dielectric build-up 210 below the conductive trace 205 (e.g., between the conductive trace 205 and second ground plane 225b) may be different from the thickness of the dielectric build-up 215 above the conductive trace 205 (e.g., between the conductive trace 205 and first ground plane 225a.

In yet further embodiments, a width of the conductive trace 205 may be variable with distance from a die package, as illustrated in greater below with respect to FIGS. 3A & 3B, which depict a cross-section taken along axis z-z, and viewed in the direction of the arrow.

FIG. 3A is a schematic diagram of a top view of a substrate 300A with variable conductive trace width. FIG. 3B is a schematic diagram of a top view of an alternative substrate 300B with variable conductive trace width, in accordance with various embodiments. FIGS. 3A & 3B include a conductive trace 305, and dielectric build-up 310. FIG. 3A depicts a discrete (e.g., step-wise) increase in the width of the conductive trace 305. As described with respect to FIG. 2, in some embodiments, the conductive trace 305 may have a first width W₁ over a first range of distances from a die package (or escape area), a second width W₂ over a second range of distances, and so on and so forth. In this way, the width of the conductive trace may increase in discrete steps with the distance away from a die package.

In various embodiments, the conductive trace 305 may be formed to have multiple widths by utilizing a multiple step etching process. This process may be referred to as a step etching or “digital reduction” process, in which the amount of the conductive trace 305 that is etched is increased in multiple steps. At each step, different sized masks may be utilized to control the width and shape of the conductive trace 305.

FIG. 3B depicts a continuous (e.g., “analogical”) increase in the width of the conductive trace 305. Thus, in some embodiments, the width of the conductive trace 305 may increase in a smooth or continuous manner as a function of distance from a die package and/or escape area of the substrate 300B. In some examples, the conductive trace 305 may be formed to have a continuous increase in width by utilizing an etching mask configured to adjust an etch rate. In some examples, a hatch pattern density of the etching mask may increase with distance away from a die package and/or escape area of the substrate 300B. Etching may occur at a faster rate closer to the escape area and slower farther away from the escape area of the substrate 300B. Accordingly, areas with a slower etch rate result in increased conductive trace 305 widths.

In some examples, the width of the conductive trace 305 may increase along with the thickness of the dielectric build-up 310, as previously described with respect to FIG. 2 (e.g. the thickness of the dielectric build-up 310 between the conductive trace 305 and ground plane (not shown)). In other embodiments, the width of the conductive trace 305 may increase independently of the thickness of the dielectric.

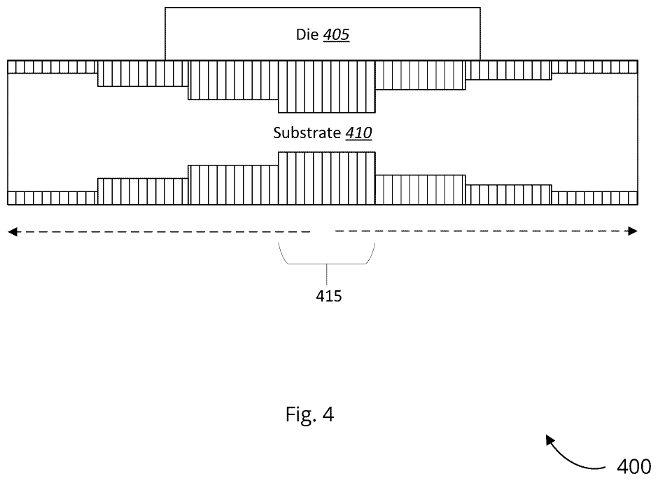

FIG. 4 of a semiconductor device 400 having a substrate with differing dielectric constants, in accordance with various embodiments. The semiconductor device 400 includes die 405, and substrate 410. It should be noted that the various components of semiconductor device 400 are schematically illustrated in FIG. 4, and that modifications to the various components and other arrangements of the semiconductor device 400 may be possible and in accordance with the various embodiments.

In various examples, the die 405 may be a semiconductor die and/or a die package coupled to the substrate 410. The die 405 may, thus, include a piece of semiconducting material on which a circuit is formed. The die 405 may be formed of a semiconducting material, such as, without limitation, silicon (Si), including silicon oxide (SiO₂, Si₃N₄, and other Si compounds) or other semiconducting material (such as GaAs, etc.). A die package may refer to a package containing the semiconductor die, and include additional elements, such as an interposer and/or die carrier substrate. The interposer and/or die carrier substrate may then couple the die package to the substrate 410.

The die 405 may be coupled to substrate 410 via a package ball area and/or an escape area 415. In this example, the escape area 415 is depicted central to the die 405 and substrate 410 for purposes of explanation. Accordingly, in various embodiments, the die 405 may be coupled to the substrate 410 via a flip-chip bonding process (e.g., solder microbumps with underfill material). In some further examples, the die 405 may be coupled to the substrate via a copper-to-copper (Cu—Cu) bonding process (e.g., hybrid copper bonding or direct copper bonding).

Accordingly, in some embodiments, the width of a conductive trace of the substrate 410 may increase with distance away from the escape area 415. In some embodiments, a thickness of the dielectric build-up (including dielectric core) of the substrate 410 may increase with distance away from the escape area 415. Correspondingly, in some examples, a thickness of a ground plane of the substrate 410 may decrease with distance away from the escape area 415. As previously described, in some further, dielectric inserts may be formed around conductive traces in the escape area 415 to reduce fringe capacitance between conductive traces in the escape area 415.

As previously described, in some examples, the substrate 410 may include a differential pair of conductive traces. A first conductive trace of the differential pair may have a first electrical length, and a second conductive trace may have a second electrical length that is longer than the first. A dielectric insert may be positioned between the second conductive trace and a ground plane (e.g., one of a first ground plane at a top surface and a second ground plane at a bottom surface) of the substrate 410. The length of the dielectric insert may be tuned to adjust for electrical skew and/or electrical length mismatch between the first conductive trace and second conductive trace. Although only a single differential pair is described for purposes of explanation, it is to be understood that in various embodiments, the substrate 410 includes a plurality conductive traces, of which there are a plurality of differential pairs. Dielectric inserts may, thus, selectively be formed and respectively tuned for specific differential pairs and/or individual conductive traces.

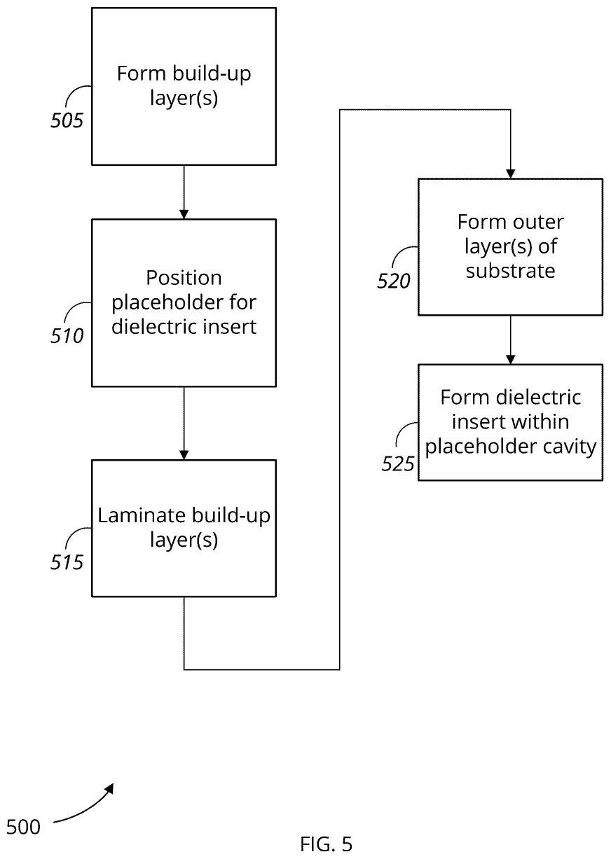

FIG. 5 is a flow diagram of a method 500 of manufacturing of manufacturing a substrate with differing dielectric constant. The method 500 includes, at block 505, forming one or more build-up layers of a substrate. As previously described, a substrate may include one or more dielectric build-up layers, which may include a dielectric core. The one or more build-up layers may be formed of a dielectric material having a first Dₖ. The dielectric build-up layers may include one or more build-up films, which may later be laminated with a dielectric core. One or more copper layers and/or interconnects, such as conductive traces, pads, or vias, may further be formed in respective build-up layers of the one or more of the one or more build-up layers.

As previously described, forming the conductive traces and/or the dielectric material of the build-up may include forming conductive traces having a width that increases with distance from an escape area and/or package ball area (e.g., pads of a substrate configured to be coupled to a chip package). Similarly, as previously described, in some examples, the dielectric build-up may be formed such that a thickness of the dielectric material increases with distance from the escape area and/or package ball area. Correspondingly, one or more ground planes may similarly be formed to have a thickness that decreases with distance from the escape area and/or package ball area.

In various embodiments, the dielectric core may itself be one or more pre-formed build-up layers. In various examples, forming the one or more build-up layers may further include ordering and aligning one or more dielectric build-up films, copper foil and/or other elements.

The method continues, at block 510, by positioning a placeholder for a dielectric insert. A placeholder may include any structure configured to hold its shape within the dielectric material during a lamination process of the substrate. The placeholder may be a solid structure formed of a polymer, resin, epoxy, or other material (e.g., glass, silicon, metal, etc.). In some examples, the placeholder may be a hollow structure, such as a tube, or a cube. The placeholder may further include one or more openings. The placeholders may be positioned over various areas of the substrate in which a dielectric insert is to be placed, as previously described. For example, in some embodiments, the placeholder may be placed between a conductive trace and ground plane. The placeholder may further be placed in and/or around one or more package ball areas (e.g., around the pads where a die package will be coupled to the substrate).

The method 500 continues, at block 515, by laminating the build-up layers to bond the build-up layers of the substrate. Lamination of the build-up layers may include creating a vacuum, pressurizing, and heating the build-up layers, as known to those skilled in the art. The method 500 further includes, at block 520, forming one or more outer layers of the substrate. Forming the outer layers of the substrate may include, for example, forming one or more drill holes (e.g., through-hole vias), metallization (e.g., plating), desmearing, and forming interconnects (e.g., traces and pads) of the outer layers (e.g., top surface and/or bottom surface) of the substrate.

The method 500 further includes, at block 525, forming a dielectric insert within a placeholder cavity. In some examples, forming a dielectric insert within a placeholder cavity includes injecting a dielectric material into a cavity formed by the placeholder. As previously described, in some examples, the placeholder may be a hollow structure comprising an internal cavity. Thus, in some examples, the placeholder defines one or more walls of a cavity. In some examples, the placeholder may be removed (e.g., drilled or chemically removed) to reveal the placeholder cavity. As previously described, the dielectric material of the dielectric insert may have a Dₖ that is different form the Dₖ of the build-up dielectric. In some examples, the Dₖ of the dielectric insert may be smaller than the Dₖ of the dielectric material of the dielectric build-up. In some examples, the dielectric material of the dielectric insert may include, without limitation, an aerogel, such as a silica aerogel or other dielectric aerogel.

The techniques and processes described above with respect to various embodiments may be used to manufacture substrates 100-300B, semiconductor device 400, and/or components thereof, as described herein.

While some features and aspects have been described with respect to the embodiments, one skilled in the art will recognize that numerous modifications are possible. For example, the methods and processes described herein may be implemented using hardware components, custom integrated circuits (ICs), programmable logic, and/or any combination thereof. Further, while various methods and processes described herein may be described with respect to particular structural and/or functional components for ease of description, methods provided by various embodiments are not limited to any particular structural and/or functional architecture but instead can be implemented in any suitable hardware configuration. Similarly, while some functionality is ascribed to one or more system components, unless the context dictates otherwise, this functionality can be distributed among various other system components in accordance with the several embodiments.

Moreover, while the procedures of the methods and processes described herein are described in a particular order for ease of description, unless the context dictates otherwise, various procedures may be reordered, added, and/or omitted in accordance with various embodiments. Moreover, the procedures described with respect to one method or process may be incorporated within other described methods or processes; likewise, system components described according to a particular structural architecture and/or with respect to one system may be organized in alternative structural architectures and/or incorporated within other described systems. Hence, while various embodiments are described with or without some features for ease of description and to illustrate aspects of those embodiments, the various components and/or features described herein with respect to a particular embodiment can be substituted, added and/or subtracted from among other described embodiments, unless the context dictates otherwise. Consequently, although several embodiments are described above, it will be appreciated that the invention is intended to cover all modifications and equivalents within the scope of the following claims.

What is claimed is:

1. An apparatus comprising:
a first conductive trace;
a first ground plane of the substrate, the first ground plane disposed on a first side of the substrate;
a second ground plane of the substrate, the second ground plane disposed on a second side of the substrate;
a first material having a first dielectric constant, wherein the first material is disposed between the first ground plane and the first conductive trace; and
a second material having a second dielectric constant, wherein the second material is disposed between the second ground plane and at least part of the first conductive trace,
wherein the first dielectric constant is different from the second dielectric constant.

2. The apparatus of claim 1, further comprising a second conductive trace, wherein the first conductive trace has a first electrical length, and the second conductive trace has a second electrical length less than the first electrical length.

3. The apparatus of claim 2, wherein the first material is disposed between the first ground plane and the second conductive trace, and between the second ground plane and the second conductive trace.

4. The apparatus of claim 1, wherein the second dielectric constant is less than the first dielectric constant.

5. The apparatus of claim 1, wherein the second material comprises an aerogel formed of a dielectric material.

6. The apparatus of claim 5, wherein the aerogel comprises a silicon-based aerogel.

7. The apparatus of claim 1, wherein a width of the first conductive trace changes along a longitudinal axis of the first conductive trace.

8. The apparatus of claim 7, wherein the width of the first conductive trace is a first width at a first step and a second width at a second step, wherein the second step occurs at a first longitudinal distance along the first conductive trace.

9. The apparatus of claim 1, wherein a thickness of at least one of the first material or the second material increases along a first direction of a longitudinal axis of the first conductive trace.

10. A semiconductor device comprising:
a substrate, wherein the substrate comprises:
a first conductive trace;
a first ground plane;
a second ground plane;
one or more layers formed of a first material having a first dielectric constant, wherein the one or more layers are disposed between the first ground plane and the first conductive trace; and
a dielectric insert, the dielectric insert formed of a second material having a second dielectric constant, wherein the dielectric insert is disposed between the second ground plane and at least part of the first conductive trace,
wherein the first dielectric constant is different from the second dielectric constant; and
a die coupled to the substrate.

11. The semiconductor device of claim 10, wherein the substrate further includes a second conductive trace, wherein the first conductive trace has a first electrical length, and the second conductive trace has a second electrical length less than the first electrical length.

12. The semiconductor device of claim 10, wherein the second dielectric constant is less than the first dielectric constant.

13. The semiconductor device of claim 10, wherein the second material comprises an aerogel formed of a dielectric material.

14. The semiconductor device of claim 13, wherein the aerogel comprises a silica aerogel.

15. The semiconductor device of claim 10, wherein a width of the first conductive trace changes along a longitudinal axis of the first conductive trace.

16. The semiconductor device of claim 15, wherein the width of the first conductive trace is a first width at a first step and a second width at a second step, wherein the second step occurs at a first longitudinal distance along the first conductive trace.

17. The semiconductor device of claim 10, wherein a thickness of the one or more layers increases along a first direction of a longitudinal axis of the first conductive trace.

18. The semiconductor device of claim 17, wherein a width of the first conductive trace increases along a longitudinal axis of the first conductive trace based, at least in part, on the thickness of the one or more layers between the first conductive trace and at least one of the first ground plane or the second ground plane at a respective point along the longitudinal axis and in a direction orthogonal to the longitudinal axis.

19. A method comprising:
forming one or more layers of a substrate from a first material having a first dielectric constant;
positioning one or more placeholders on at least one of the one or more layers, each placeholder of the one or more placeholders defining walls of a respective cavity of one or more cavities;
laminating the one or more layers; and
forming a dielectric insert within the one or more cavities formed by the placeholders.

20. The method of claim 19, wherein forming the dielectric insert within the one or more cavities further includes injecting a second material into the one or more cavities, the second material having a second dielectric constant lower than the first dielectric constant.
